(19) United States
(12) Patent Application Publication
(10) Pub. No.: US 2013/0015914 A1
(43) Pub. Date: Jan. 17, 2013

(54) SIGNAL TRANSMITTING METHODS AND TRANSMITTERS USING THE SAME

(71) Applicants: Kuo-Hao Chen, Hsinchu City (TW); Yen-Shuo Lu, Kaohsiung City (TW)

(72) Inventors: Kuo-Hao Chen, Hsinchu City (TW); Yen-Shuo Lu, Kaohsiung City (TW)

(73) Assignee: MEDIATEK INC., Hsin-Chu (TW)

(21) Appl. No.: 13/181,191

(22) Filed: Jul. 12, 2011

(51) Int. Cl. H03K 5/00

(52) U.S. Cl. 327/551

(57) ABSTRACT

An exemplary embodiment of a transmitter of the invention is provided. The transmitter includes a shaping means and a digital-to-analog converter (DAC). The shaping means digitally shapes a digital signal. The DAC is arranged to convert the shaped digital signal into an analog signal. The shaping means is arranged to decrease energy at an edge of an in-band portion of a frequency spectrum of the digital signal so as to lower a spectral re-growth of the analog signal happened after the DAC.

### BACKGROUND OF THE INVENTION

1. Field of the Invention

The invention relates to a signal transmitting method, and more particularly to a transmitter using the signal processing method to relax spectral re-growth.

2. Description of the Related Art

In a conventional communication system, spectral re-growth may occur at an output signal of a power amplifier in a transmitter due to a non-linear characteristic of the transmitter path. Spectral re-growth would be more severe when the required output power of the transmitter increases. The appearance of the spectral re-growth causes a signal frequency spectrum at the output would violate the specification requirement of the transmitter. Accordingly, the transmission quality of the transmitter may be unqualified due to the spectral re-growth issue.

Thus, it is desired to have a solution which may relax spectral re-growth at an output of a transmitter.

### BRIEF SUMMARY OF THE INVENTION

An exemplary embodiment of a transmitter is provided. The transmitter includes a shaping means and a digital-to-analog converter (DAC). The shaping means digitally shapes a digital signal. The DAC is arranged to convert the shaped digital signal into an analog signal. The shaping means is arranged to decrease energy at an edge of an in-band portion of a frequency spectrum of the digital signal so as to lower a spectral re-growth of the analog signal happened after the DAC.

In some embodiments, the shaping means includes a filter. The filter decreases the energy at the edge of the in-band portion of the frequency spectrum of the digital signal by a frequency response of the filter. The digital signal is a signal modulated with orthogonal frequency-division multiplexing (OFDM) or complementary code keying (CCK).

In some other embodiments, the shaping means includes a baseband source. Before an inverse fast Fourier transform (iFFT) operation, the baseband adjusts weightings of subcarriers of the digital signal in the in-band portion to decrease the energy at the edge of the in-band portion of the frequency spectrum of the digital signal. The digital signal is a signal modulated with orthogonal frequency-division multiplexing (OFDM) by the baseband source.

An exemplary embodiment of a signal transmitting method is further provided. The signal processing method includes the steps of: digitally shaping a digital signal by decreasing energy at an edge of an in-band portion of a frequency spectrum of the digital signal; and converting the shaped digital signal into an analog signal. The energy at the edge of the in-band portion of the frequency spectrum of the digital signal is decreased so as to lower a spectral re-growth of the analog signal happened after the shaped digital signal is converted into the analog signal.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an exemplary embodiment of a transmitter;

FIG. 2 shows a frequency spectrum of an analog signal amplified by a power amplifier with a digital shaping operation and a frequency spectrum of an analog signal amplified by the power amplifier without any digital shaping operation according to the transmitter of FIG. 1;

FIG. 3 shows frequency response of a filter with and without a digital shaping operation according to the transmitter of FIG. 1;

FIG. 4A shows a frequency spectrum of an analog signal amplified by the power amplifier without a digital shaping operation when a digital signal is a signal modulated with complementary code keying (CCK);

FIG. 4B shows a frequency spectrum of an analog signal amplified by a power amplifier with a digital shaping operation performed by a shaping means when a digital signal is a signal modulated with CCK according to the transmitter of FIG. 1;

FIG. 5 shows another exemplary embodiment of a transmitter;

FIG. 6 shows adjustment of weightings of subcarriers of a digital signal in the in-band portion of the frequency spectrum of the digital signal according to the transmitter of FIG. 5;

FIG. 7A shows a frequency spectrum of an analog signal amplified by a power amplifier without any digital shaping operation; and

FIG. 7B shows frequency spectrum of an analog signal amplified by a power amplifier with a digital shaping operation performed by a shaping means according to the transmitter of FIG. 5.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

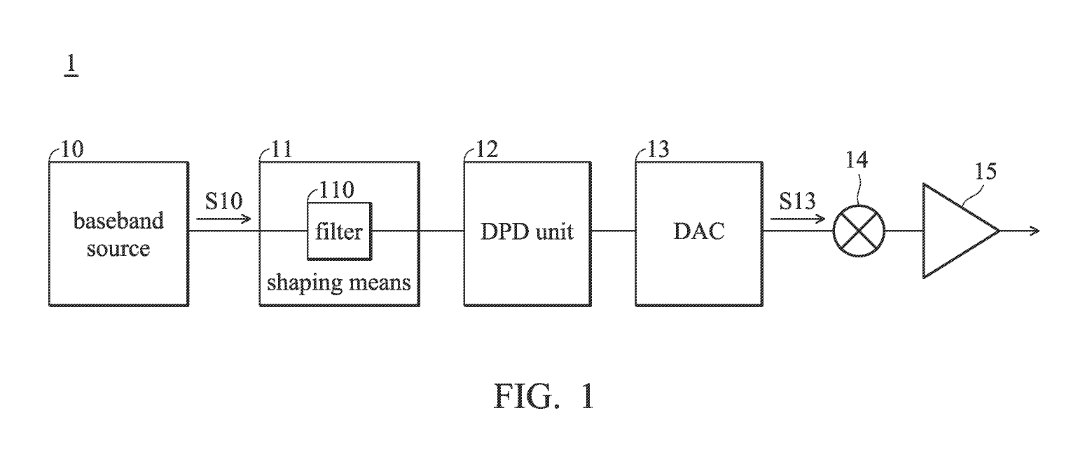

In an exemplary embodiment of a transmitter of the invention in FIG. 1, a transmitter 1 includes a baseband source 10, a shaping means 11, a digital pre-distortion (DPD) unit 12, a digital-to-analog converter (DAC) 13, a mixer 14, and a power amplifier 15 to perform a signal transmitting method. The baseband source 10 provides a digital signal S10. The shaping means 11 receives the digital signal S10 and digitally shapes the digital signal S10. In the embodiment, the shaping means 11 shapes the digital signal S10 by decreasing energy at an edge of an in-band portion of a frequency spectrum of the digital signal S10. The DPD unit 12 performs a digital linear process to the shaped digital signal. The digital-to-analog converter (DAC) 13 converts the shaped digital signal, which has been processed by the DPD unit 12 with the digital linear process, into an analog signal S13. The mixer 14 receives and up-converts the analog signal S13. In other words, the mixer 14 performs up-conversion to the analog signal S13. The power amplifier 15 receives and amplifies the analog signal S13 which has been up-converted by the mixer 14. The transmitter 1 transmits the amplified analog signal S13 to a corresponding receiver (not shown).

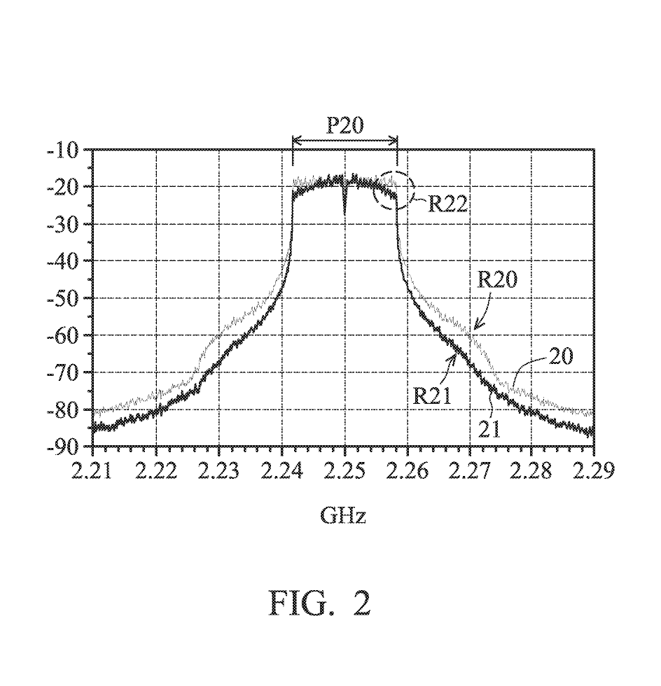

FIG. 2 shows frequency spectrums of signals which are amplified by the power amplifier 15 with the digital shaping operation and without any digital shaping operation. In FIG. 2, the label “21” represents the frequency spectrum of the analog signal S13 which is amplified by the power amplifier 15 with the digital shaping operation performed by the shaping means 11. The label “20” represents the frequency spectrum of an analog signal amplified by the power amplifier 15 without any digital shaping operation. In other words, the energy at the edge of the in-band portion of the frequency spectrum of the digital signal S10 is not decreased by the shaping means 11. Referring to FIG. 2, in a right sidelong portion of the frequency spectrum 20, there is a spectral re-growth R20 due to a nonlieaner characteristic of the power amplifier 15. A portion P20 shown in FIG. 2 corresponds to the in-band portion of the frequency spectrum of the digital signal S10. Referring to FIG. 2, with the decrement of the energy at the edge of the in-band portion of the frequency spectrum of the digital signal S10, the energy at the edge of the portion P20 of the frequency spectrum 21 is less than that of the frequency spectrum 20, as indicated by a circular range R22. Accordingly, a spectral re-growth R21 of the analog signal S13 amplified by the power amplifier 15 is lowered. So, the spectral re-growth R21 with the digital shaping operation is advantageously lower than the spectral re-growth R20 without any digital shaping operation, for example, by 5 dB.

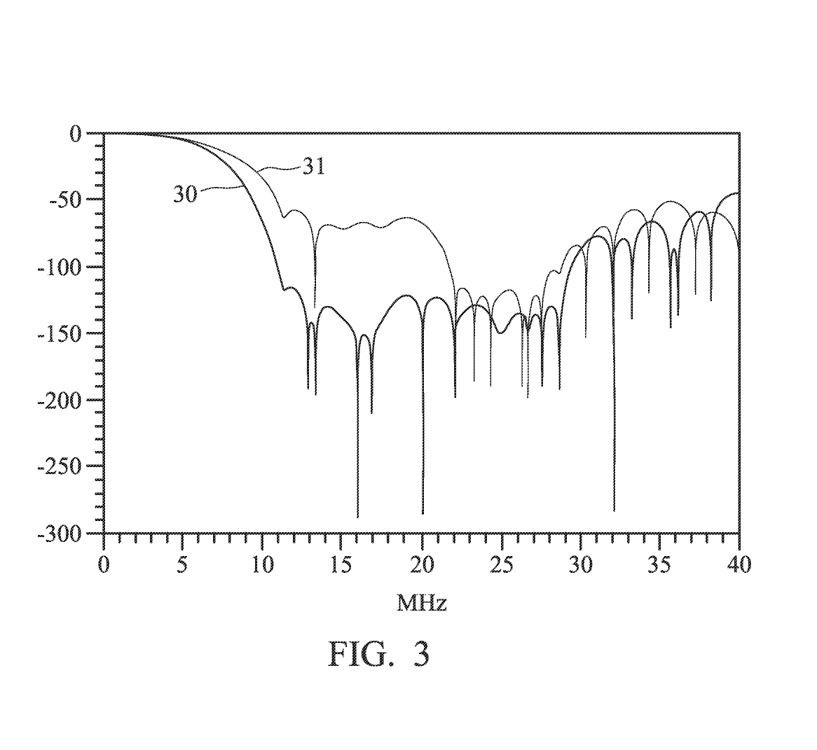

In the embodiment, the shaping means 11 includes a filter 110 and digitally shapes the digital signal S10 by the filter 110. The filter 110 may decrease the energy at the edge of the in-band portion of the frequency spectrum of the digital signal S10 by a frequency response of the filter 110. In order to achieve the digital shaping operation, parameters of the filter 110 have to be particularly set or adjusted, so that the energy at the edge of the in-band portion of the frequency spectrum of the digital signal S10 is decreased. In the embodiment, the parameters of the filter 110 may be set or adjusted for the digital shaping operation during the manufacturing thereof, and the parameters are fixed after the manufacture. Alternatively, the parameters of the filter 110 may be adjustable and set or adjusted when the transmitter 1 is operating. FIG. 3 shows frequency response 30 of the filter 110 with the digital shaping operation and frequency response 31 of the filter 110 without any digital shaping operation. The frequency response 31 of the filter 110 is obtained when the parameters of the filter 110 are not set or adjusted for the digital shaping operation. Referring to FIG. 3, the overall amplitude response of the filter 110 with the digital shaping operation is lower than the overall amplitude response of the filter 110 without any digital shaping operation. In the embodiment, the filter 110 is implemented by a digital-type filter, such as a Bessel low-pass filter, a finite impulse response (FIR) filter, or an infinite impulse response (IIR) filter. The above filters are given as an example without limitation. Any digital-type filter with parameters which can be set or adjusted for the digital shaping operation may serve as the filter 110.

According to the signal transmitting method described in the above embodiment of FIGS. 1-3, the shaping means 11 decreases the energy at the edge of the in-band portion of the frequency spectrum of the digital signal S10 by the frequency response of the filter 110. Accordingly, a spectral re-growth of the analog signal S13 happened after the DAC 13 is relaxed. The frequency spectrum of the analog signal S13 amplified by the power amplifier 15 may match a standard specified by a specification of the transmitter 1, so that the transmission quality of the transmitter 1 can be upgraded.

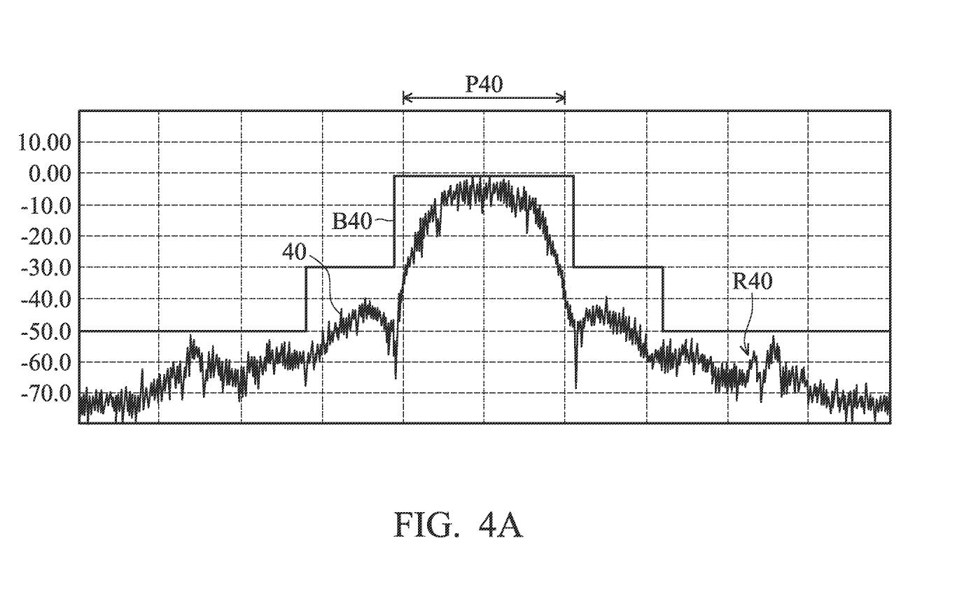

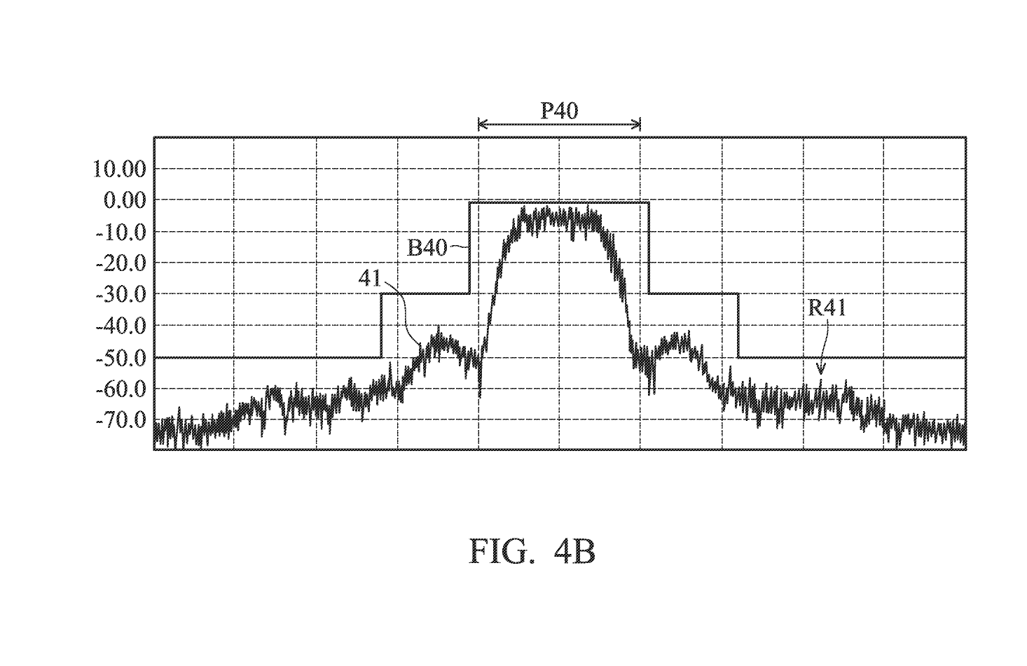

In some embodiments, the digital signal S10 provided by the baseband source 10 may be a signal modulated with orthogonal frequency-division multiplexing (OFDM) or complementary code keying (CCK) by the baseband source 10. The modulation using OFDM or CCK by the baseband source 10 is given as an example. However, the baseband source 10 may modulate the digital signal S10 with any other communication modulation, such as WCDMA, LTE, etc., according to system requirements. FIG. 4A shows a frequency spectrum of an analog signal which is amplified by the power amplifier 15 without any digital shaping operation when the baseband source 10 modulates the digital signal S10 with CCK. FIG. 4B shows a frequency spectrum of the analog signal S13 which is amplified by the power amplifier 15 with the digital shaping operation when the baseband source 10 modulates the digital signal S10 with CCK. A frequency spectrum boundary B40 shown in FIGS. 4A and 4B is defined by a standard specified by the specification of the transmitter 1. The portion P40 shown in FIGS. 4A and 4B corresponds to the in-band portion of the frequency spectrum of the digital signal S10. In FIG. 4A, the label “40” represents the frequency spectrum of the analog signal amplified by the power amplifier 15 without any digital shaping operation. In other words, the energy at the edge of the in-band portion of the frequency spectrum of the digital signal S10 is not decreased by the shaping means 11. In a right sidelong portion of the frequency spectrum 40, there is a spectral re-growth R40 of the analog signal amplified by the power amplifier 15 due to a nonlieaner characteristic of the power amplifier 15. The spectral re-growth R40 causes the frequency spectrum 40 to exceed the frequency spectrum boundary B40. In FIG. 4B, the label “41” represents the frequency spectrum of the analog signal S13 which is amplified by the power amplifier 15 with the digital shaping operation performed by the shaping means 11. Referring to FIGS. 4A and 4B, with the decrement of the energy at the edge of the in-band portion of the frequency spectrum of the digital signal S10, the energy at the edge of the portion P40 of the frequency spectrum 41 is lowered. Accordingly, a spectral re-growth R41 of the analog signal S13 amplified by the power amplifier 15 is lowered. By comparing the frequency spectrum 40 with the frequency spectrum 41, it is shown that the energy at the edge of the portion P40 of the frequency spectrum 41 is less than the energy at the edge of the portion P40 of the frequency spectrum 40. The spectral re-growth R41 with the digital shaping operation is advantageously lower than the spectral re-growth R40 without any digital shaping operation. In one example, the frequency spectrum 41 does not exceed the frequency spectrum boundary B40.

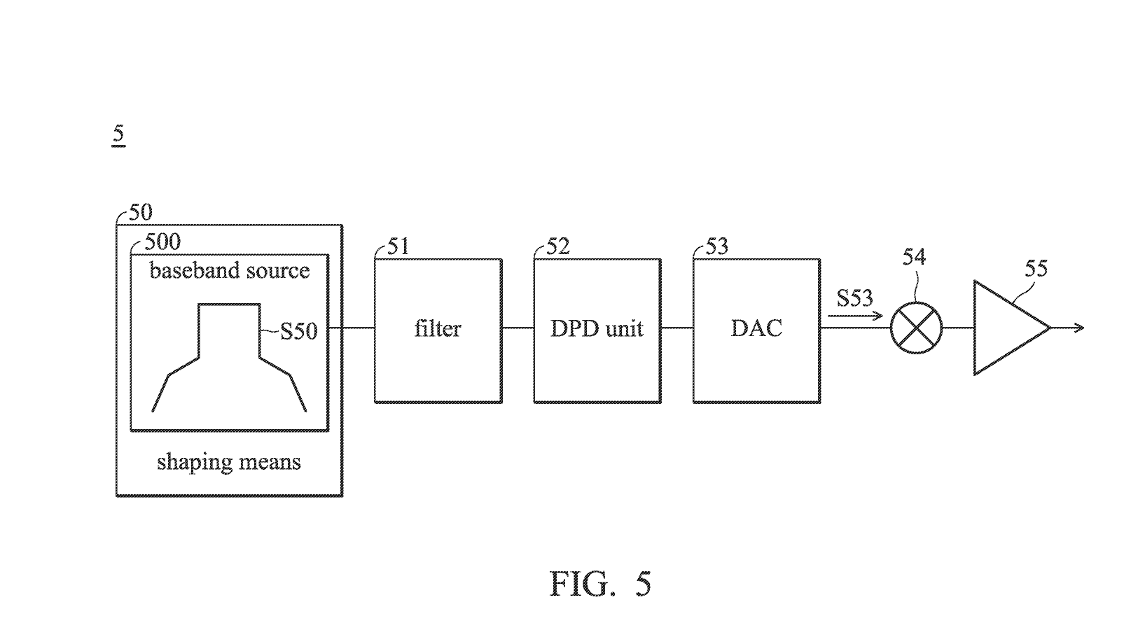

FIG. 5 shows another exemplary embodiment of a transmitter of the invention. As shown in FIG. 5, a transmitter 5 includes a shaping means 50, a filter 51, a digital pre-distortion (DPD) unit 52, a digital-to-analog converter (DAC) 53, a mixer 54, and a power amplifier 55 to perform a signal transmitting method. The shaping means 50 digitally shapes a digital signal S50. In the embodiment, the shaping means 50 shapes the digital signal S 10 by decreasing energy at an edge of an in-band portion of a frequency spectrum of the digital signal S50. The filter 51 receives the shaped digital signal from the shaping means 50 and performs a filtering operation to the shaped digital signal. The DPD unit 52 performs a digital linear process to the shaped digital signal. The digital-to-analog converter (DAC) 53 converts the shaped digital signal, which has been processed by the DPD unit 52 with the digital linear process, into an analog signal S53. The mixer 54 receives and up-converts the analog signal S53. In other words, the mixer 54 performs up-conversion to the analog signal S53. The power amplifier 55 receives and amplifies the analog signal S53 which has been up-converted by the mixer 54. The transmitter 5 transmits the amplified analog signal S53 to a corresponding receiver (not shown).

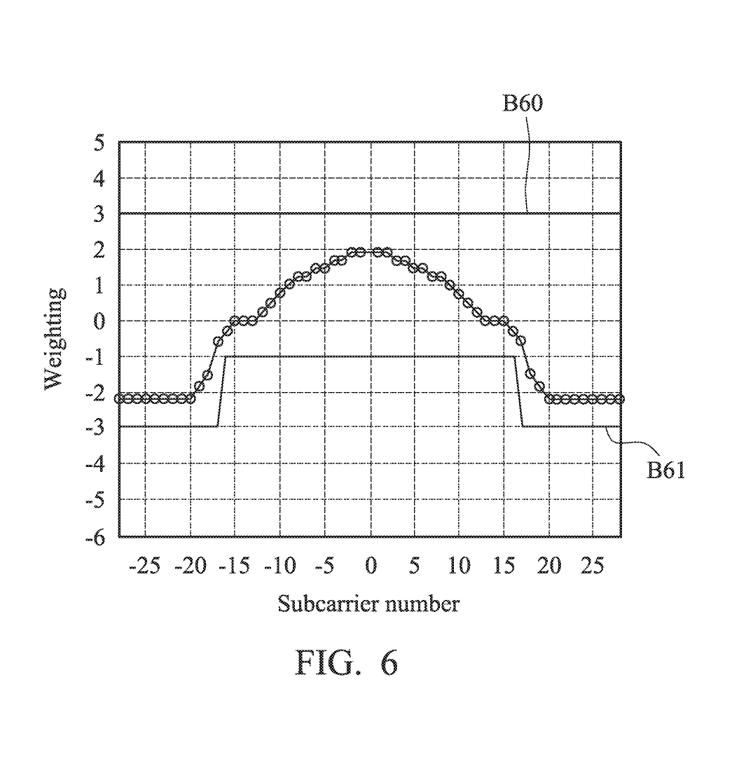

In the embodiment, the shaping means 50 includes a baseband source 500 and digitally shapes the digital signal S50 by the baseband source 500. The baseband source 500 may perform an inverse fast Fourier transform (iFFT) operation. Moreover, in the embodiment, the digital signal S50 is a signal modulated with orthogonal frequency-division multiplexing (OFDM) by the baseband source 500, and the digital signal S50 includes a plurality of subcarriers. For example, there are fifty-two subcarriers in the in-band portion of the frequency spectrum of the digital signal S50. As shown in FIG. 6, in order to achieve the digital shaping operation, the baseband source 500 adjusts weightings of the fifty-two subcarriers of the digital signal S50 in the in-band portion, so that the energy at the edge of the in-band portion of the frequency spectrum of the digital signal S50 is decreased. The adjusted weightings of the fifty-two subcarriers of the digital signal S50 in the in-band portion is still between the weighting boundaries B60 and B61 which are defined by a standard specified by the specification of the transmitter 5. In some embodiments, the adjustment of the weightings of the fifty-two subcarriers of the digital signal S50 in the in-band portion may be performed before the iFFT operation.

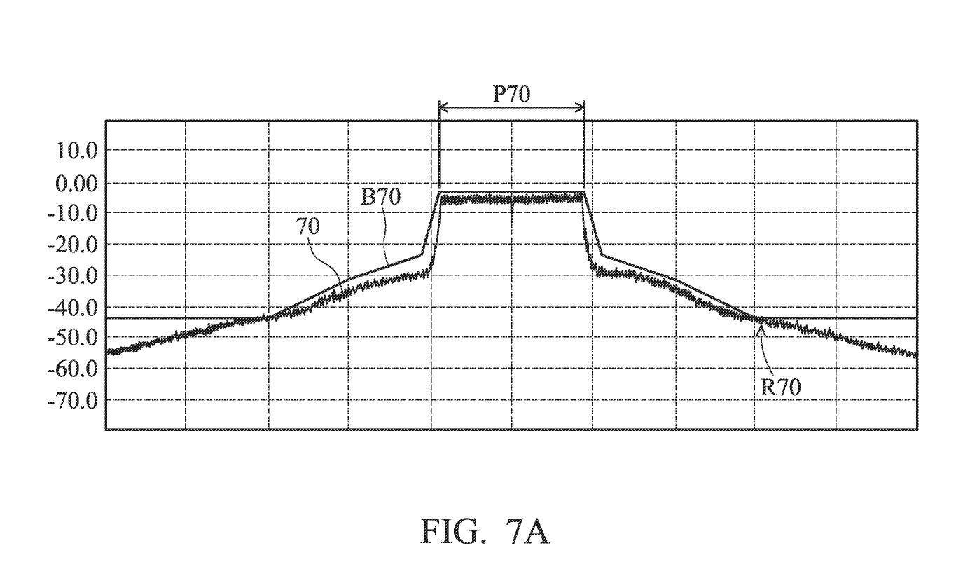

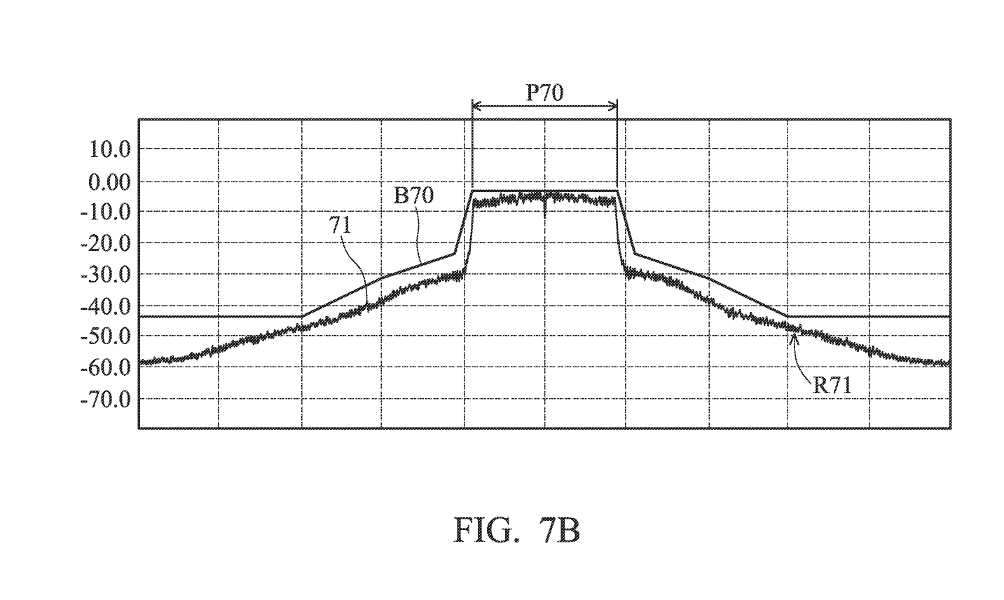

FIG. 7A shows a frequency spectrum of an analog signal which is amplified by the power amplifier 55 without any digital shaping operation. FIG. 7B shows a frequency spectrum of the analog signal S53 which is amplified by the power amplifier 55 with the digital shaping operation performed by the shaping means 50. The frequency spectrum boundary B70 shown in FIGS. 7A and 7B is defined by a standard specified by the specification of the transmitter 5. The portion P70 shown in FIGS. 7A and 7B corresponds to the in-band portion of the frequency spectrum of the digital signal S50. In FIG. 7A, the label “70” represents the frequency spectrum of the analog signal which is amplified by the power amplifier 55 without any digital shaping operation. In other words, the weightings of the fifty-two subcarriers of the digital signal S50 in the in-band portion are not adjusted by the baseband source 500 of the shaping means 50, and the energy at the edge of the in-band portion of the frequency spectrum of the digital signal S50 is not decreased. In a right sidelong portion of the frequency spectrum 70, there is a spectral re-growth R70 of the analog signal amplified by the power amplifier 55 due to a nonlieaner characteristic of the power amplifier 55, and the spectral re-growth R70 exceeds the frequency spectrum boundary B70. In FIG. 7B, the label “71” represents the frequency spectrum of the analog signal S53 which is amplified by the power amplifier 55 with the digital shaping operation performed by the shaping means 50. Referring to FIGS. 7A and 7B, with the decrement of the energy at the edge of the in-band portion of the frequency spectrum of the digital signal S50, the energy at the edge of the portion P70 of the frequency spectrum 71 is lowered. Accordingly, a spectral re-growth R71 of the analog signal S53 amplified by the power amplifier 55 is lowered. By comparing the frequency spectrum 70 with the frequency spectrum 71, it is shown that the energy at the edge of the portion P70 of the frequency spectrum 71 is less than the energy at the edge of the portion P70 of the frequency spectrum 70. The spectral re-growth R71 with the digital shaping operation is advantageously lower than the spectral re-growth R70 without any digital shaping operation. Preferably, the spectral re-growth R71 does not exceed the frequency spectrum boundary B70.

According to the signal transmitting method described in the above embodiment of FIGS. 5-7, the shaping means 50 decreases the energy at the edge of the in-band portion of the frequency spectrum of the digital signal S50 with the adjustment of the weightings of the subcarriers of the digital signal S50 in the in-band portion by the baseband source 500. Accordingly, a spectral re-growth of the analog signal S53 happened after the DAC 53 is relaxed. The frequency spectrum of the analog signal S53 which is amplified by the power amplifier 55 can meet a specification requirement of the transmitter 5, so that the transmission quality of the transmitter 5 is acceptable.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A transmitter comprising:
a shaping means for digitally shaping a digital signal ; and
a digital-to-analog converter (DAC), arranged to convert the shaped digital signal into an analog signal,
wherein the shaping means is arranged to decrease energy at an edge of an in-band portion of a frequency spectrum of the digital signal so as to lower a spectral re-growth of the analog signal happened after the DAC.

2. The transmitter as claimed in claim 1, wherein the shaping means comprises a filter for decreasing the energy at the edge of the in-band portion of the frequency spectrum of the digital signal by a frequency response of the filter.

3. The transmitter as claimed in claim 2, wherein the filter is a Bessel low-pass filter, a finite impulse response (FIR) filter, or an infinite impulse response (IIR) filter.

4. The transmitter as claimed in claim 1 further comprising a baseband source for providing the digital signal to the shaping means.

5. The transmitter as claimed in claim 1, wherein the digital signal is a signal modulated with orthogonal frequency-division multiplexing (OFDM) or complementary code keying (CCK).

6. The transmitter as claimed in claim 1 further comprises a digital pre-distortion unit for performing a digital linear process to the shaped digital signal.

7. The transmitter as claimed in claim 1, wherein the shaping means comprises a baseband source for adjusting weightings of subcarriers of the digital signal in the in-band portion to decrease the energy at the edge of the in-band portion of the

8. The transmitter as claimed in claim 7, wherein the baseband source is arranged to adjust the weightings of the subcarriers of the digital signal in the in-band portion before an inverse fast Fourier transform (iFFT) operation.

9. The transmitter as claimed in claim 7 further comprising a filter for receiving the shaped digital signal from the baseband source and performing a filtering operation to the shaped digital signal.

10. The transmitter as claimed in claim 7, wherein the digital signal is a signal modulated with orthogonal frequency-division multiplexing (OFDM) by the baseband source.

11. A signal transmitting method comprising:
digitally shaping a digital signal by decreasing energy at an edge of an in-band portion of a frequency spectrum of the digital signal; and
converting the shaped digital signal into an analog signal,
wherein the energy at the edge of the in-band portion of the frequency spectrum of the digital signal is decreased so as to lower a spectral re-growth of the analog signal happened after the shaped digital signal is converted into the analog signal.

12. The signal transmitting method as claimed in claim 11, wherein the step of digitally shaping the digital signal comprises:
performing a low-pass filtering operation to the digital signal by a filter; and
decreasing the energy at the edge of the in-band portion of the frequency spectrum of the digital signal by a frequency response of the filter.

13. The signal transmitting method as claimed in claim 12, wherein the filter is Bessel low-pass filter, a finite impulse response (FIR) low pass filter, or an infinite impulse response (IIR) low pass filter.

14. The signal transmitting method as claimed in claim 12 further comprising providing the digital signal to the filter from a baseband source.

15. The signal transmitting method as claimed in claim 11, wherein the digital signal is a signal modulated with orthogonal frequency-division multiplexing (OFDM) or complementary code keying (CCK) by the baseband source.

16. The signal transmitting method as claimed in claim 11 further comprises performing a digital linear process to the shaped digital signal.

17. The signal transmitting method as claimed in claim 11, wherein the step of digitally shaping the digital signal comprises adjusting weightings of subcarriers of the digital signal in the in-band portion by a baseband source to decrease the energy at the edge of the in-band portion of the frequency spectrum of the digital signal.

18. The signal transmitting method as claimed in claim 17, wherein the weightings of the subcarriers of the digital signal in the in-band portion is adjusted by the baseband before an inverse fast Fourier transform (iFFT) operation.

19. The signal transmitting method as claimed in claim 17 further comprising performing a filtering operation to the shaped digital signal from the baseband source.

20. The signal transmitting method as claimed in claim 17, wherein the digital signal is a signal modulated with orthogonal frequency-division multiplexing (OFDM) by the baseband source.
